(19) United States
(12) Patent Application Publication
(10) Pub. No.: US 2002/0175143 A1
(43) Pub. Date: Nov. 28, 2002

(54) Processes for polishing wafers

(75) Inventor: Steven P. Cooper, Battle Ground, WA (US)

Correspondence Address: OLIFF & BERRIDGE, PLC, P.O. BOX 19928, ALEXANDRIA, VA, 22320, US

(73) Assignee: SEH AMERICA, INC., Vancouver, WA (US)

(21) Appl. No.: 09/861,543

(22) Filed: May 22, 2001

(51) Int. Cl. B44C 1/22; H01L 21/302

(52) U.S. Cl. 216/38; 438/692

(57) ABSTRACT

Processes for polishing acid etched wafers include contacting wafers, such as a silicon wafers, with an aqueous hydrogen peroxide solution, and then polishing the wafers with an aqueous alkaline slurry. The processes can prevent edge stain by forming a passivation layer on the wafers.

### BACKGROUND OF THE INVENTION

1. Field of Invention

This invention is directed to the field of manufacturing semiconductor wafers. More specifically, this invention is directed to processes for polishing wafers, during the preparation phase and polishing phase of wafer production.

2. Description of Related Art

Semiconductor wafers, such as silicon wafers, are used for fabricating integrated circuits. Before integrated circuits can be made, wafers must be produced. Wafer production is a multi-part process. First, a semiconductor ingot is grown, often by the Czochralski method of pulling crystal, and shaped. The ingot is then sliced into wafers and prepared, through multiple steps, for polishing, in a process often referred to as the chemical wafer, or “CW,” process. The wafer is then polished and inspected in the polished wafer, or “PW,” process. Depending on end-use, the polished wafers are optionally subjected to a process by which an epitaxial layer is deposited on the wafer in the epitaxy, or “Epi,” process.

In the crystal growing process, the semiconductor material, such as crystalline silicon, is grown to create an ingot. The ingot is subsequently ground to an accurate diameter, and then alignment flats or notches are ground into the ingot. In the next phase of wafer fabrication, the ingot is sliced to create wafers. Subsequent to slicing, the wafers are subjected to edge-grinding. Edge grinding creates wafers with beveled edges and a final diameter. Edge grinding reduces the incidence of chipping. Chipping is undesirable because it produces particulates, and because a chip on a wafer is a propagation site for fractures that can occur as the wafer is subjected to stress from temperature changes and film depositions during the remainder of the fabrication process. Fracture damage in a single wafer can substantially reduce the overall yield of semiconductor wafers. The wafers are subjected to a lapping process to flatten and remove slicing damage incurred during the preceding step, then laser marked.

After lapping and laser marking, the wafers are subjected to a post-lap clean, and then an alkali clean. Following alkali cleaning, wafers are subjected to chemical etching, which removes damage and creates a smooth finish. After acid etching, wafers may be gettered externally, edge polished and/or annealed. Depending on the incidence of external gettering, the wafers are edge polished, or subjected to an annealing process. Wafers are annealed to stabilize resistivity.

Chemical etching conducted during the chemical wafer process typically leaves a rough surface on the edge of the wafers. Production of silicon wafers for use as semiconductor chips requires that wafers be ground to an exact diameter, and that the outer edge of the wafers be defect free down to a microscopic level. For this reason, the wafers are edge polished during the chemical wafer process. Edge polishing is conducted using standard polishing slurry solutions to smooth out the roughened edge resulting from etching and to further reduce stress caused by edge grinding to the precise diameters required. Edge polishing results in a mirror like surface that resists adhesion of contaminating particulates, and prevents fracture.

The standard polishing solutions used in edge polishing are aqueous, alkaline colloidal silica-containing slurries. Although the polishing process is directed to the edge alone, occasionally alkaline slurry can splash on the back and/or front surfaces of the silicon wafers. These splashes cause unwanted etching on the surface(s) of the wafers. This undesirable etching effect becomes increasingly noticeable over time as the evaporation of water increases the concentration of caustic in the slurry. When the resulting etching is visible under fluorescent or halogen light, the wafer is rejected as unacceptable product due to “edge stain,” which is a micro-defect on the edge of the surface of the wafer that appears as microscopic pitting or other etch phenomena.

There are known methods to reduce the occurrence of edge stain. One method includes the chemical cleaning of silicon wafers referred to as “SC-1 cleaning.” SC-1 cleaning is known to be effective in preventing edge-stain. SC-1 cleaning solution is comprised of ammonium hydroxide, hydrogen peroxide, and water. However, SC-1 cleaning has its disadvantages. SC-1 solution is expensive. In addition, including SC-1 cleaning in the process of manufacturing semiconductor chips requires the addition of steps for chemical and waste water treatment. Thus, SC-1 cleaning increases the complexity and the cost of semiconductor chip manufacture.

Although it is known that silicon oxide layers may be formed on wafers by exposing them to oxygen at elevated temperatures, alkaline impurities, such as sodium and potassium salts, are thought to diffuse rapidly through the formed oxide layers, even at low temperatures (Runyan et al., Semiconductor Integrated Circuit Processing Technology, pp. 69-70 (1990)). In light of this knowledge, more dense dielectric films, such as silicon nitride, are often used in combination with the oxide to passivate the wafers against such impurities. Ibid., p. 72. Since an edge polishing slurry is alkaline, containing sodium and/or potassium salts, formation of silicon oxide layers on wafers should not prevent edge-stain.

However, U.S. Pat. No. 5,972,802 to Nakano et al. (“Nakano”) discloses that silicon oxide layers can be effective to prevent edge stain, and also teaches an alternative method to SC-1 cleaning for preventing edge stain. In the method, acid-etched wafers are dipped in water charged with ozone to create a silicon oxide passivation layer. This passivation layer protects the surface of the wafer during the process of edge polishing. The use of ozonated water to prevent edge stain is a less elaborate technique than SC-1 cleaning, in that special steps for chemical and waste water clean up are not required. In spite of this improvement, the creation of an ozonated water bath can be sufficiently expensive that use of the Nakano process is not fully satisfactory in the production of semiconductor wafers.

U.S. Pat. No. 5,837,662 to Chai et al. (“Chai”) teaches a process for cleaning wafers after the lapping process described above. Chai addresses the problems associated with using many-stepped processes involving sustained exposure to sonic energy to clean lapped wafers. Chai teaches the use of an oxidizing agent such as ozone or SC-1 solution to oxidize impurities on the surface of the wafer. Chai does not disclose a process of polishing acid-etched wafers in a manner that prevents edge stain.

U.S. Pat. No. 6,063,205 to Cooper et al. (“Cooper”) also teaches a process for post-lap cleaning. Cooper addresses the problems associated with a post-lap cleaning process that uses many steps, and large volumes of reagents. Cooper teaches the use of a hydrogen peroxide bath to clean wafers that have been subjected to lapping. Cooper does not disclose a method of polishing acid-etched wafers.

Thus, there is a need for a wafer polishing process that eliminates the time and waste problems associated with SC-1 cleaning and the expense of the Nakano process, and provides a simple, inexpensive method of preventing edge-stain when polishing acid-etched wafers.

### SUMMARY OF THE INVENTION

This invention provides processes for polishing wafers that satisfy the above needs. More particularly, embodiments of the processes for polishing wafers protect wafer surfaces not subjected to polishing (i.e. the wafer backside) from the effects of polishing slurry. The processes can protect semiconductor materials subject to polishing by creating a passivation layer. The processes can effectively and inexpensively prevent the occurrence of edge stain on semiconductor materials. In addition, embodiments of the processes can provide a wafer surface suitable for integrated circuit fabrication.

Generally, this invention is directed to processes for polishing surfaces of semiconductor wafers, after the wafers have been acid-etched. The surfaces of the wafers that are not subsequently polished are not damaged during the polishing of the wafers. Embodiments of the processes comprise contacting wafers with an aqueous solution comprising hydrogen peroxide to form oxide layers. The aqueous solution does not contain ammonium hydroxide, which would be the case with an SC-1 solution. The wafers having oxide layers are then polished with an aqueous alkaline slurry without subjecting the wafers to pre-polish cleaning.

### DETAILED DESCRIPTION OF PREFERRED EMBODIMENTS

As described above, after the surfaces of wafers, such as silicon wafers, have been acid-etched, a somewhat roughened finish is left on the edges of the wafers. In embodiments of the processes of this invention, edge staining of wafers is prevented by contacting wafers with hydrogen peroxide prior to polishing the wafers. The processes can be employed whenever acid-etched silicon wafers are polished with an alkaline slurry, and the unpolished surfaces of the wafers need to be protected from detrimental effects of the slurry. The processes are particularly advantageous following acid-etching and following high-temperature annealing in the chemical wafer process.

In embodiments of the processes of this invention, an aqueous solution comprising hydrogen peroxide passivates the surface of a silicon wafer by forming a silicon oxide layer on the surface of the wafer. The silicon oxide layer forms by the reaction of the hydrogen peroxide solution with the suspending or binding compounds of the wafer. The wafer, having a silicon oxide layer on its surface, is then polished. Slurry that contacts the unpolished backside of the wafer does not cause unwanted pitting, stain, or other unwanted slurry-related phenomena, because the backside is protected by the oxide layer. The oxide layer is removed at a later stage in the process of wafer manufacture.

In a preferred embodiment, the acid-etched semiconductor wafer is contacted with an aqueous hydrogen peroxide solution that is free of ammonium hydroxide. As described, ammonium hydroxide is present in SC-1 cleaning solutions. Use of aqueous solutions containing ammonium hydroxide require additional steps for chemical and waste water treatment not required by the use of aqueous hydrogen peroxide solutions. The wafer is contacted with the aqueous hydrogen peroxide for at least the amount of time that is effective to form an oxide layer on the surface of the wafer. The wafer is preferably contacted with the aqueous hydrogen peroxide for at least 30 seconds. More preferably, the wafer is contacted with the aqueous hydrogen peroxide for from about 30 seconds to about 30 minutes, even more preferably for from about 1 minute to about 10 minutes. Most preferably, the wafer is contacted with the aqueous hydrogen peroxide for from about 1 minute to about 4 minutes.

The aqueous hydrogen peroxide solution has a sufficient concentration of hydrogen peroxide to form an oxidation layer on a wafer. The concentration of the aqueous hydrogen peroxide solution can be from about 0.5% to about 20% hydrogen peroxide by weight. Preferably the concentration of the solution is from about 1% to about 10% hydrogen peroxide by weight. More preferably, the concentration of the solution is from about 5% to about 7% hydrogen peroxide by weight. Most preferably, the concentration of the aqueous hydrogen peroxide solution is about 6% hydrogen peroxide by weight.

The wafer can be contacted with the aqueous hydrogen peroxide solution by any suitable process. For example, the wafer can be contacted with the aqueous hydrogen peroxide solution by either spraying the aqueous solution on the wafer or by submerging the wafer in a bath of hydrogen peroxide. Preferably, the wafer is submerged in a bath of hydrogen peroxide, which can reduce consumption of the solution.

The wafers are rinsed with deionized water and dried by conventional techniques. The wafers are then polished with an aqueous alkaline slurry.

This invention is illustrated by the following example, which is merely for the purpose of illustration and is not to be regarded as limiting the scope of the invention, or the manner in which it may be practiced.

### EXAMPLE

Twenty-six boron-doped silicon wafers are stripped with hydrofluoric acid (HF) to simulate the worst-case condition of wafers that have progressed through the chemical etching step in the process of wafer manufacture. Following HF stripping, the wafers are spin dried and boxed. To prevent oxidation while the wafers are boxed, testing is preferred within two hours of HF stripping. A 6% by weight aqueous solution of hydrogen peroxide that is free of ammonium hydroxide is created in a quartz beaker. Twenty of the stripped wafers are dipped in the aqueous hydrogen peroxide solution for about four minutes. The hydrogen peroxide-dipped wafers are then spray rinsed with deionized water for about thirty seconds and dried in an isopropyl alcohol dryer. The remaining six wafers are not subjected to the hydrogen peroxide dipping process, and serve as a control group.

Following the above steps, ten hydrogen peroxide-dipped wafers and two control wafers are edge polished with an aqueous, alkaline colloidal silica-containing slurry by a first edge polishing/notch polishing machine that is in continuous operation just prior to the time of the test. An additional ten hydrogen peroxide-dipped wafers and four control wafers are edge polished by a second edge polishing/notch polishing machine that has been idle for about 8 hours at the time of the test, using a new aqueous alkaline colloidal silica-containing slurry (pH 10.6).

Following edge/notch polishing, all twenty-six wafers are visually inspected under halogen and fluorescent light. All six control wafers show edge stain that would result in rejection in the wafer manufacturing process. The control wafers that are subjected to edge polish by the polishing machine using a new slurry demonstrate visible stains under fluorescent light. None of the wafers subjected to hydrogen-peroxide dipping show edge-stain that would result in rejection from the production process when subjected to visual inspection. Additionally, after front surfaces are polished, control wafers experience rejectable backside stain, while hydrogen peroxide dipped wafers experience no such stain.

The test results demonstrate that hydrogen peroxide dipping according to embodiments of the invention is effective in preventing edge stain, without time and waste problems associated with SC-1 cleaning, and without expense associated with ozone dipping.

While this invention has been described in conjunction with the specific embodiments above, it is evident that many alternatives, combinations, modifications, and variations are apparent to those skilled in the art. Accordingly, the preferred embodiments of this invention, as set forth above are intended to be illustrative, and not limiting. Various changes can be made without departing from the spirit and scope of this invention.

What is claimed is:

1. A process for polishing an acid-etched wafer, comprising:
(a) contacting a wafer that has been acid-etched with an aqueous solution comprising hydrogen peroxide and free of ammonium hydroxide, thereby forming an oxide layer on the wafer; and
(b) then polishing the wafer with an aqueous alkaline slurry without subjecting the wafer to pre-polish cleaning.

2. The process of claim 1, wherein (a) is conducted for an amount of time effective to form an oxide layer on the wafer.

3. The process of claim 1, wherein (a) is conducted for from about 30 seconds to about 30 minutes.

4. The process of claim 1, wherein (a) is conducted for from about 1 minute to about 10 minutes.

5. The process of claim 1, wherein (a) is conducted for from about 1 minute to about 4 minutes.

6. The process of claim 1, wherein the aqueous solution comprises a concentration of hydrogen peroxide effective to form the oxide layer.

7. The process of claim 1, wherein the aqueous solution comprises from about 0.5% to about 20% hydrogen peroxide by weight.

8. The process of claim 1, wherein the aqueous solution comprises from about 1% to about 10% hydrogen peroxide by weight.

9. The process of claim 1, wherein the aqueous solution comprises from about 5% to about 7% hydrogen peroxide by weight.

10. The process of claim 1, wherein the aqueous solution comprises about 6% hydrogen peroxide by weight.

11. The process of claim 1, wherein the wafer is contacted with the aqueous solution by submerging the wafer in the aqueous solution.

12. The process of claim 1, wherein the wafer is contacted with the aqueous solution by spraying the aqueous solution onto the wafer.

13. The process of claim 1, wherein the wafer is comprised of silicon.

14. A process for edge polishing an acid-etched wafer comprising:
(a) contacting a wafer with an aqueous solution comprising hydrogen peroxide and free from ammonium hydroxide, thereby forming an oxide layer on the wafer; and
(b) then polishing an edge of the wafer with an aqueous alkaline slurry without subjecting the wafer to pre-polish cleaning;
wherein contact of the wafer with the aqueous solution reduces edge staining of the wafer during (b).

15. The process of claim 14, wherein (a) is conducted for an amount of time effective to form an oxide layer on the wafer.

16. The process of claim 14, wherein (a) is conducted for from about 30 seconds to about 30 minutes.

17. The process of claim 14, wherein (a) is conducted for from about 1 minute to about 10 minutes.

18. The process of claim 14, wherein (a) is conducted for from about 1 minute to about 4 minutes.

19. The process of claim 14, wherein the aqueous solution comprises a concentration of hydrogen peroxide effective to form the oxide layer.

20. The process of claim 14, wherein the aqueous solution comprises from about 0.5% to about 20% hydrogen peroxide by weight.

21. The process of claim 14, wherein the aqueous solution comprises from about 1% to about 10% hydrogen peroxide by weight.

22. The process of claim 14, wherein the aqueous solution comprises from about 5% to about 7% hydrogen peroxide by weight.

23. The process of claim 14, wherein the aqueous solution comprises about 6% hydrogen peroxide by weight.

24. The process of claim 14, wherein the wafer is contacted with the aqueous solution by submerging the wafer in the aqueous solution.

25. The process of claim 14, wherein the wafer is contacted with the aqueous solution by spraying the aqueous solution onto the wafer.

26. The process of claim 14, wherein the wafer is comprised of silicon.

27. A process for edge polishing an acid-etched silicon wafer comprising:
(a) contacting a silicon wafer, that has been acid-etched, with an aqueous solution comprising hydrogen peroxide, in a concentration effective to form an oxide layer on the wafer, and free of ammonium hydroxide, for an amount of time effective to form the oxide layer on the wafer; and
(b) then polishing an edge of the wafer with an aqueous alkaline slurry without subjecting the wafer to pre-polish cleaning;
wherein contact of the wafer with the aqueous solution reduces edge staining of the wafer during (b).
